(19) United States
(12) Patent Application Publication
(10) Pub. No.: US 2017/0236760 A1
(43) Pub. Date: Aug. 17, 2017

(54) LIGHT-EMITTING DIODE LIGHTING DEVICE AND METHOD FOR REPAIRING THE SAME

(71) Applicant: MIKRO MESA TECHNOLOGY CO., LTD., APIA (WS)

(72) Inventors: Li-Yi CHEN, Tainan City (TW); Pei-Yu CHANG, Tainan City (TW); Chih-Hui CHAN, Tainan City (TW); Chun-Yi CHANG, Tainan City (TW); Shih-Chyn LIN, Tainan City (TW); Hsin-Wei LEE, Tainan City (TW)

(21) Appl. No.: 15/044,117

(22) Filed: Feb. 16, 2016

(51) Int. Cl. H01L 21/66; H01L 33/42; H01L 33/62; H01L 33/40

(52) U.S. Cl. CPC H01L 22/14; H01L 33/405; H01L 33/42; H01L 33/62; H01L 2933/0066

(57) ABSTRACT

A method for repairing a light-emitting diode (LED) lighting device is provided. The method includes the operations below. First, the LED lighting device is obtained. The LED lighting device includes a substrate having a top surface and a recess, a first bottom electrode disposed on the top surface and on a bottom surface of the recess, a second bottom electrode disposed on the top surface, an LED disposed in the recess and on the first bottom electrode, and a top transparent electrode disposed on the LED and the second bottom electrode. Then, a test is performed to know whether the first bottom electrode, the LED, the top transparent electrode, and the second bottom electrode form a part of an electrical loop. Finally, a connecting member is formed to electrically connect the first bottom electrode and the second bottom electrode if the electrical loop is open.

### BACKGROUND

In recent years, light-emitting diode (LED) technologies have been improved a lot, and LEDs with high power and high brightness have been presented to the market. In addition, the LEDs used as light bulbs have the advantage of long lifetime. Therefore, such LED light sources have the tendency to replace other conventional light sources and be the dominant technology in the illumination industry.

Since LEDs gradually become mainstream light sources, improving properties of LEDs becomes an important issue, and this becomes the main goal in the R&D departments of the LED industries.

### SUMMARY

In one aspect of the disclosure, a method for repairing a light-emitting diode (LED) lighting device is provided. The method includes operations below. First, the LED lighting device is provided. The LED lighting device includes a substrate having a top surface and a first recess therein, a first bottom electrode disposed on the top surface and on a bottom surface of the first recess, a second bottom electrode disposed on the top surface, at least one first LED disposed in the first recess and on the first bottom electrode, and a first top transparent electrode disposed on the first LED and the second bottom electrode. Then, a test is performed to know whether the first bottom electrode, the first LED, the first top transparent electrode, and the second bottom electrode form a part of a first electrical loop. Finally, at least one first connecting member is formed to electrically connect the first bottom electrode and the second bottom electrode if the first electrical loop is open.

In another aspect of the disclosure, an LED lighting device is provided. The LED lighting device includes a substrate, at least one first bottom electrode, at least one second bottom electrode, at least one LED, at least one top transparent electrode, and at least one conductive member. The substrate has a top surface and at least one recess therein. The recess has a bottom surface. The first bottom electrode is disposed on the top surface and on the bottom surface. The second bottom electrode is disposed on the top surface. The LED is disposed in the recess and on the first bottom electrode. The top transparent electrode is disposed on the LED and the second bottom electrode. The conductive member is electrically connecting the first bottom electrode and the second bottom electrode.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a flow chart of a method for repairing a light-emitting diode (LED) lighting device according to one embodiment of this disclosure;

FIG. 2A is a schematic cross-sectional view of an intermediate step in the method for repairing the LED lighting device according to one embodiment of the present disclosure;

FIGS. 2B and 3 are schematic top views of intermediate steps in a method for repairing the LED lighting device according to one embodiment of the present disclosure; and

FIG. 4 is a schematic top view of an intermediate step in a method for repairing the LED lighting device according to another embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically depicted in order to simplify the drawings.

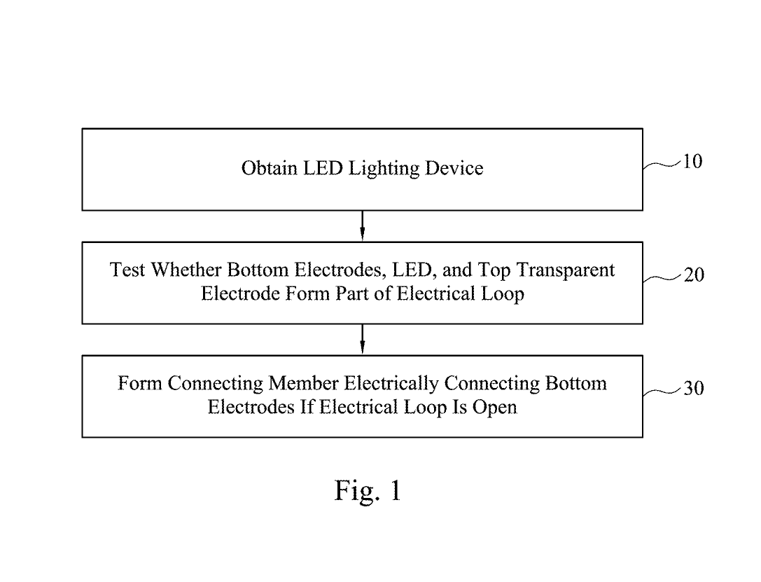

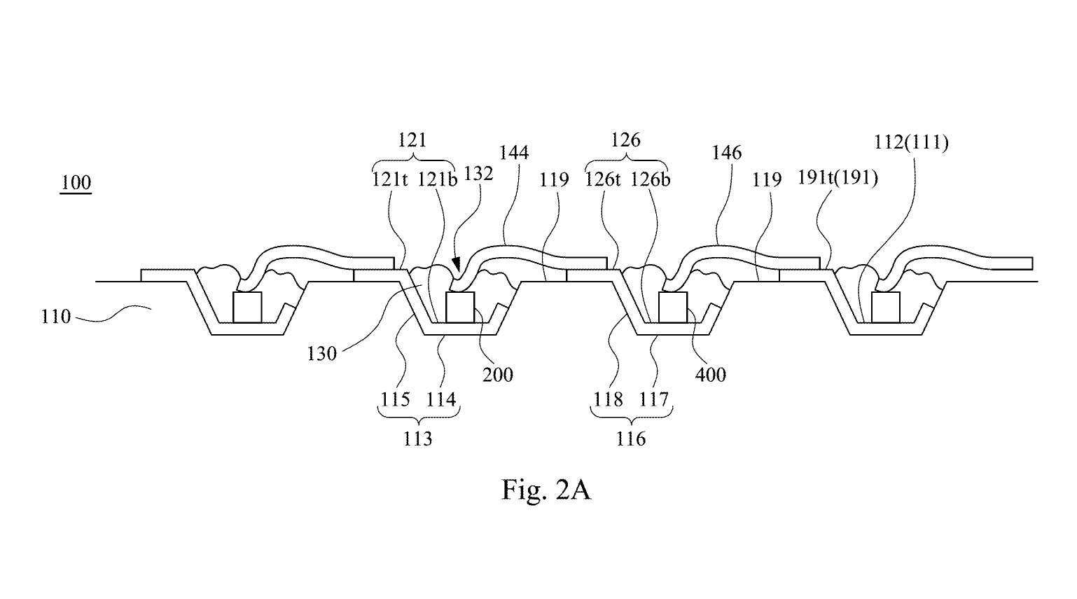

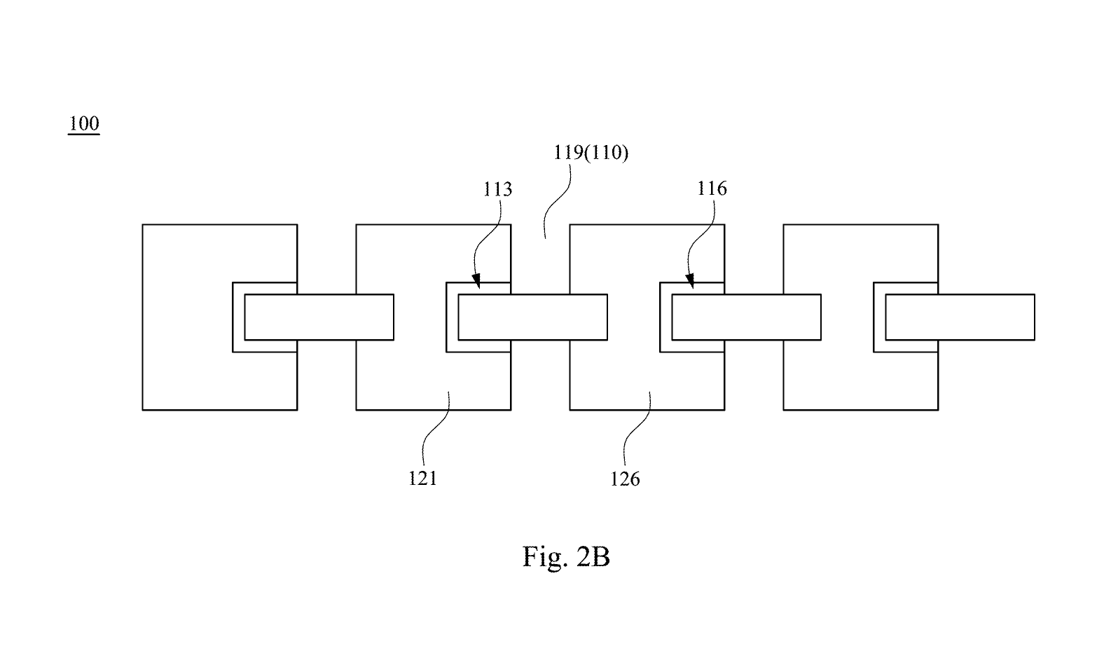

FIG. 1 is a flow chart of a method for repairing a light-emitting diode (LED) lighting device 100 according to one embodiment of this disclosure. FIG. 2A is a schematic cross-sectional view of an intermediate step in the method for repairing the LED lighting device 100 according to one embodiment of the present disclosure. As shown in FIGS. 1 and 2A, a method for repairing an LED lighting device 100 is provided. The LED lighting device 100 includes a plurality of vertical LEDs, such as the LEDs 200 and 400, connected in series, such that the LED lighting device 100 can achieve high power and high luminous efficiency. However, since the LEDs are connected in series, if one of the LEDs is damaged, the entire electrical loop may be open, such that the LED lighting device 100 cannot be operated well. Therefore, the method is provided to solve such problem. The method includes operations below.

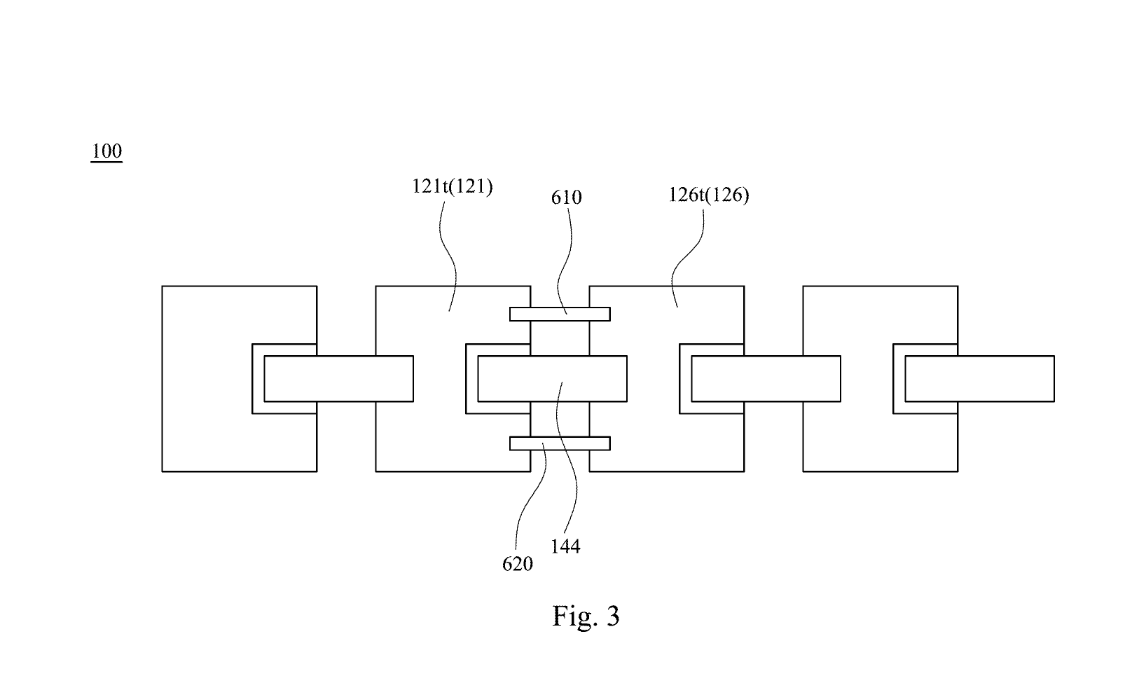

FIGS. 2B and 3 are schematic top views of intermediate steps in a method for repairing the LED lighting device 100 according to one embodiment of the present disclosure. First, as shown in FIGS. 1, 2A, and 2B, operation 10 is obtaining the LED lighting device 100. The LED lighting device 100 includes a substrate 110, at least two bottom electrode, at least one LED, and at least one top transparent electrode. The substrate 110 has a top surface 119 and at least one recess therein, and the substrate 110 is made of one piece of material. One of the bottom electrodes is disposed on the top surface 119 and on a bottom surface of the recess, and the other of the bottom electrodes is disposed on the top surface 119. The LED is disposed in the recess and on the bottom electrode in the recess. The top transparent electrode is disposed on the LED and the other of the bottom electrodes, which is not disposed in the recess.

For example, a top part 121t of a bottom electrode 121 is disposed on the top surface 119, and a bottom part 121b of a bottom electrode 121 is disposed on a bottom surface 114 of a recess 113. A top part 126t of a bottom electrode 126 is disposed on the top surface 119, and a bottom part 126b of a bottom electrode 126 is disposed on a bottom surface 117 of a recess 116. An LED 200 is disposed in the recess 113 and on the bottom part 121b of the bottom electrode 121, and an LED 300 is disposed in the recess 116 and on a bottom part 126b of the bottom electrode 126. A top transparent electrode 144 is disposed on the LED 200 and the top part 126t of the bottom electrode 126.

Specifically, an area of an orthographic projection of the bottom electrode 121 onto the substrate 110 is greater then an area of the recess 113, and an area of an orthographic projection of the bottom electrode 126 onto the substrate 110 is greater then an area of the recess 116.

Specifically, an overlapping area of orthographic projections of the bottom electrode 121 and the top transparent electrode 144 onto the substrate 110 is less than the area of an orthographic projection of the bottom electrode 121 onto the substrate 110.

In the embodiment, the LEDs are vertical LEDs. Embodiments of this disclosure are not limited thereto. People having ordinary skill in the art can make proper modifications to the LEDs depending on the actual application.

Operation 20 is testing whether the bottom electrodes, the LEDs, and the top transparent electrodes form a part of an electrical loop. Specifically, in some embodiment, the test may be performed by electrically connecting the top part 121t of the bottom electrode 121 and the top part 126t of the bottom electrode 126. Since the top part 121t of the bottom electrode 121 and the top part 126t of the bottom electrode 126 are not covered or blocked by other components, the test can be easily performed.

For example, the bottom electrode 121, the LED 200, the top transparent electrode 144, and the bottom electrode 126 may form a part of a first electrical loop.

If one of the bottom electrode 121, the LED 200, the top transparent electrode 144, and the bottom electrode 126 is damaged, or if one of electrical connections between the bottom electrode 121, the LED 200, the top transparent electrode 144, and the bottom electrode 126 is not properly formed, the first electrical loop is open. Then, the entire electrical loop of the LED lighting device 100 is open as well, such that the LED lighting device 100 cannot be operated well.

As shown in FIGS. 1 and 3, operation 30 is forming at least one connecting member to electrically connect the bottom electrodes if the electrical loop is open.

For example, connecting members 610 and 620 are formed to electrically connect the bottom electrodes 121 and 126. Therefore, even though the first electrical loop is open, the entire loop of the LED lighting device 100 skip the open part, and the LED lighting device 100 can still be operated well.

If the first electrical loop is found open, i.e., some parts of the LED lighting device 100 are not properly electrically connected, the entire LED lighting device 100 cannot be operated well. By the repair method provided here, the entire loop of the LED lighting device 100 skip the open part, so the LED lighting device 100 can still be operated well.

Because of the special structure of the LED lighting device 100, the LEDs are covered by the top transparent electrode, so it's difficult to directly fix the LEDs if the LEDs are damaged. Since the connecting member is formed to electrically connect the top parts of the bottom electrodes on the top surface 119, such as the top part 121t of the bottom electrode 121 and the top part 126t of the bottom electrode 126, the top parts of the bottom electrode are not covered, so the repair method is easy to be performed.

Specifically, the connecting member is formed by conductive paste dispensing, soldering, wire bonding, or any other good conductive connection methods. Embodiments of this disclosure are not limited thereto. People having ordinary skill in the art can make proper modifications to the forming method of the connecting member depending on the actual application.

In the embodiment, two connecting members 610 and 620 are formed. Embodiments of this disclosure are not limited thereto. In other embodiments, only one connecting member may be formed, or more than two connecting members may be formed.

After the operation 20 is performed, the LED lighting device 100 can be classified into a first level if the first electrical loop is formed or a second level if the first electrical loop is open. Then, the operation 30 is performed for the LED lighting device 100 in the second level.

The repair method can be performed during manufacturing process of the LED lighting device 100. Then, the LED lighting device 100 in the first level can achieve the maximum brightness, and the LED lighting device 100 in the second level can achieve a lower brightness than the brightness achieved by the LED lighting device 100 in the first level. The LED lighting devices 100 in the first level and the second level all can be operated well and can be used for different functions. Therefore, even when one of the LEDs of LED lighting device 100 is damaged, the LED lighting device 100 can still be repaired. Thus, the process yield of the LED lighting devices 100 is increased, and the manufacturing cost of the LED lighting devices 100 is reduced.

The LED lighting device 100 may be classified into more than two levels. One example is illustrated below.

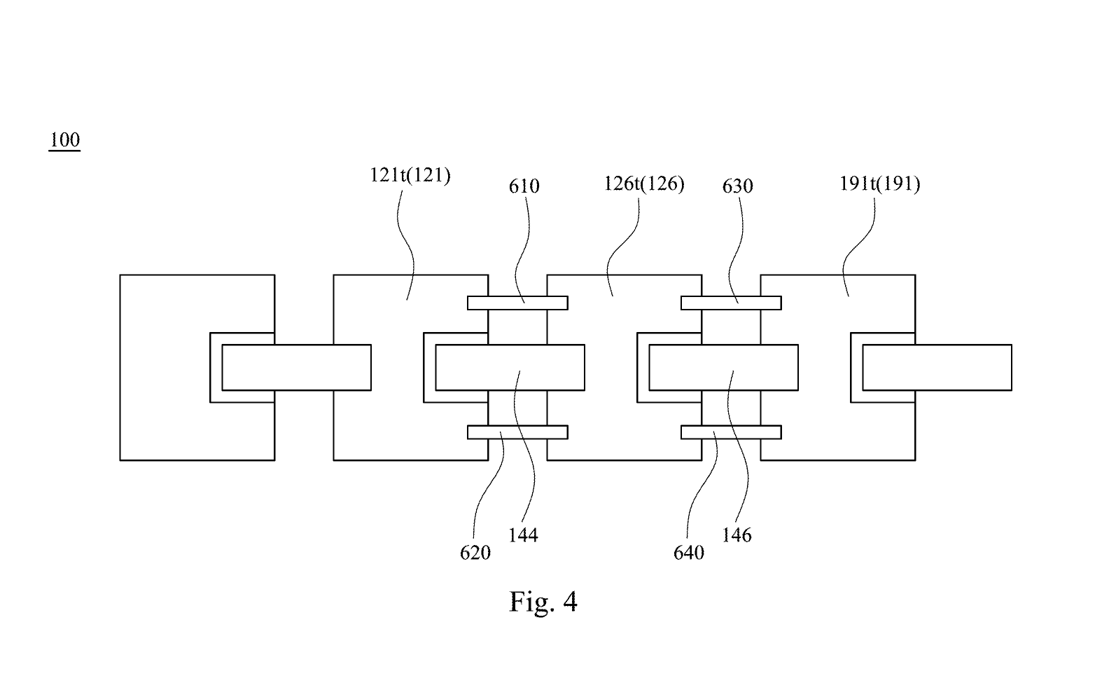

FIG. 4 is a schematic top view of an intermediate step in a method for repairing the LED lighting device 100 according to another embodiment of the present disclosure. As shown in FIGS. 2A and 4, the substrate 110 further has a recess 111. A bottom electrode 191 is disposed on the top surface 119 and a bottom surface 112 of the recess 111. Specifically, a top part 191t of the bottom electrode 191 is disposed on the top surface 119. The top transparent electrode 146 is disposed on the LED 400 and the top part 191t of the bottom electrode 191.

When the operation 20 is performed, a test is also performed to know whether the bottom electrode 126, the LED 400, the top transparent electrode 146, and the bottom electrode 191 form a part of a second electrical loop.

After the operation 20 is performed, the LED lighting device 100 is classified into a first level if both the first and second electrical loops are properly formed, a second level if one of the first and second electrical loops are properly formed, or a third level if both the first and second electrical loops are open. Then, the operation 30 is performed for the LED lighting device 100 in the second level or the third level.

When the operation 30 is performed, at least one connecting member is also formed to electrically connect the bottom electrodes 126 and 191 if the second electrical loop is open. Specifically, the connecting members 630 and 640 are formed to electrically connect the bottom electrodes 126 and 191.

As shown in FIGS. 2A and 3, in another aspect of the disclosure, an LED lighting device 100 is provided. The LED lighting device 100 includes a substrate 110, at least one bottom electrode 121, at least one bottom electrode 126, at least one LED 200, at least one top transparent electrode 144, and at least one conductive member, such as the conductive member 610 and 620. The substrate 110 has a top surface 119 and at least one recess 113 therein. The recess 113 has a bottom surface 114. The bottom electrode 121 is disposed on the top surface 119 and on the bottom surface 114 of the recess 113. The bottom electrode 126 is disposed on the top surface 119. The LED 200 is disposed in the recess 113 and on the bottom electrode 121. The top transparent electrode 144 is disposed on the LED 200 and the bottom electrode 126. The conductive member is electrically connecting the bottom electrodes 121 and 126.

Specifically, an electrical loop among the bottom electrode 121, the LED 200, the top transparent electrode 144, and the bottom electrode 126 is open.

Specifically, the conductive member is made of tin, gold, silver, copper, aluminum, or any other good conductor. Embodiments of this disclosure are not limited thereto. People having ordinary skill in the art can make proper modifications to the conductive member depending on the actual application.

In the embodiment, two connecting members 610 and 620 are formed. Embodiments of this disclosure are not limited thereto. In other embodiments, only one connecting member may be formed, or more than two connecting members may be formed.

In the embodiment, the bottom electrodes are single layered and reflective. More specifically, the bottom electrodes are made of metal, such as silver. Embodiments of this disclosure are not limited thereto. In other embodiments, the bottom electrodes may be multi-layer structures. For example, the bottom electrodes are double-layer structures made of copper and silver or triple-layer structures made of copper, titanium, and silver.

Specifically, the recess 113 has at least one side surface 115 sloping between the top surface 119 and the bottom surface 114 of the recess 113 (the recess 116 may also has at least one side surface 118 sloping between the top surface 119 and the bottom surface 117 of the recess 116). In addition, at least a part of the bottom electrode 121 is disposed on the side surface 115.

The LED lighting device 100 further includes a transparent isolation layer 130 in the recess 113 to adjust optical paths of the LED 200. The bottom transparent isolation layer 130 has an opening 132 therein to expose at least a part of the LED 200.

The LED lighting device 100 may further include additional phosphor layer and additional transparent isolation layer disposed above the recess 113 and on the transparent isolation layer 130 and the top transparent electrode 144. The LED lighting device 100 may further include an encapsulation layer to cover the recess 113 and the LED 200.

In the embodiment, only one LED 200 is formed in the recess 113 and on the bottom electrode 121. Embodiments of this disclosure are not limited thereto. In other embodiments, a plurality of the LEDs may be formed in the same recess and on the same bottom electrode, and one of the top transparent electrodes and one of the bottom electrodes cooperate to electrically connect the LEDs in the same recess in parallel.

Additionally, as shown in FIG. 2A, the LED 200 has a top surface, and a height of the top surface of the LED 200 is lower than a height of the top surface 119 of the substrate 110. Therefore, lateral light emitted from the vertical LED 200 is reflected by the bottom electrode 121, and there are rooms to dispose additional transparent isolation layers or phosphor layers in the recess 113 to adjust optical paths, such that light efficiency of the LED lighting device 100 is optimized.

The LED lighting device 100 includes only one substrate, i.e., the substrate 110, and all other structures are stacked on the substrate 110. Therefore, the manufacturing process of the LED lighting device 100 become easy, and problems such as alignment difficulty are avoided, such that the process yield is enhanced and the manufacturing cost is lowered.

If some parts of the entire electrical loop of the LED lighting device 100 is found open, the entire loop of the LED lighting device 100 is open, and the LED lighting device 100 cannot be operated well. By the repair method provided here, the entire loop of the LED lighting device 100 skip the open part, so the LED lighting device 100 can still be operated well.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C. §112, 6th paragraph. In particular, the use of “step of” in the claims herein is not intended to invoke the provisions of 35 U.S.C. §112, 6th paragraph.

1-8. (canceled)

9. A light-emitting diode (LED) lighting device, comprising:
a substrate having a top surface and a recess therein, wherein the recess has a bottom surface;
at least one first bottom electrode comprising a first portion disposed on the top surface and a second portion disposed on the bottom surface;
at least one second bottom electrode comprising a third portion disposed on the top surface;
at least one LED disposed in the recess and on the first bottom electrode;
at least one top transparent electrode disposed on the LED and the second bottom electrode; and
at least one conductive member electrically connecting and physically connecting the first portion of the first bottom electrode and the third portion of the second bottom electrode.

10. The LED lighting device of claim 9, wherein an electrical loop among the first bottom electrode, the LED, the top transparent electrode, and the second bottom electrode is open.

11. The LED lighting device of claim 9, wherein the conductive member is made of tin, gold, silver, copper, or aluminum.

12. The LED lighting device of claim 9, wherein a single of the at least one conductive member is electrically connecting the first bottom electrode and the second bottom electrode.

13. The LED lighting device of claim 9, wherein a plurality of the conductive member is electrically connecting the first bottom electrode and the second bottom electrode.

14. The LED lighting device of claim 9, wherein the LED is a vertical LED.

15. The LED lighting device of claim 9, wherein the first bottom electrode is reflective.

16. The LED lighting device of claim 9, wherein the first bottom electrode is made of metal.

17. The LED lighting device of claim 9, wherein the first bottom electrode is single-layered.

18. The LED lighting device of claim 9, wherein the first bottom electrode is multi-layered.

19. The LED lighting device of claim 9, wherein the recess has at least one side surface sloping between the top surface and the bottom surface.

20. The LED lighting device of claim 19, wherein at least a part of the first bottom electrode is disposed on the side surface.
